(19) United States
(12) Patent Application Publication
(10) Pub. No.: US 2026/0095137 A1
(43) Pub. Date: Apr. 2, 2026

(54) BUZZER DEVICE, DRIVING SYSTEM FOR A BUZZER AND METHOD THEREOF

(71) Applicant: NUVOTON TECHNOLOGY CORPORATION, HSINCHU CITY (TW)

(72) Inventors: Pao-Shu Chang, Zhubei City (TW); Chih-Wei Tsai, Zhubei City (TW)

(21) Appl. No.: 19/335,603

(22) Filed: Sep. 22, 2025

Related U.S. Application Data
(60) Provisional application No. 63/701,378, filed on Sep. 30, 2024.

(30) Foreign Application Priority Data
Jan. 24, 2025 (TW) 114103455

(51) Int. Cl. H03G 3/30; G10K 9/122

(52) U.S. Cl. CPC H03G 3/3005; G10K 9/122; H03G 2201/103

(57) ABSTRACT

A driving system for a buzzer is provided. The driving system includes a driving unit and a boost unit. The driving unit receives an analog audio and outputs a driving voltage to the buzzer according to the analog audio. The boost unit is electrically connected to the driving unit, generates a working voltage by boosting an input voltage and transmits the working voltage to the driving unit. The driving system generates the driving voltage through an analog signal to improve an output audio quality of the buzzer.

### CROSS-REFERENCE TO RELATED APPLICATION

This application claims the priority benefit of U.S. Provisional Application No. 63/701,378 filed on Sep. 30, 2024, and claims priority of application No. 114103455, filed in Taiwan on Jan. 24, 2025, the full disclosures of which is incorporated herein by reference.

### BACKGROUND

### Technical Field

The present invention relates to a driving system and a method for driving a buzzer, and more particularly, to a driving system and a driving method capable of driving the buzzer to operate through an analog signal.

### Description of Related Art

A buzzer is widely used as a sound-emitting component in products such as alarms, multimedia devices, automotive electronic equipment, and toys. Buzzers are mainly classified into piezoelectric and electromagnetic types. When a buzzer is powered, its internal metal diaphragm vibrates within the resonance chamber to produce sound.

Conventional buzzers are primarily driven by digital signals. As a result, most buzzers can only emit a single tone, and sound details are easily filtered out by the buzzer, leading to poor output sound quality that is difficult to compare with that of a speaker. However, compared to speakers, buzzers still possess irreplaceable advantages such as small size, high volume, low cost, and durability. Accordingly, how to address the existing issues of buzzers remains one of the key challenges for related industries.

### SUMMARY

In view of the foregoing, an aspect of the present invention is to provide a driving system and a method for driving a buzzer through an analog signal, so as to improve the sound quality of the buzzer and enable the buzzer to reproduce sound details contained in the audio signal.

To achieve the aforementioned aspects, the driving system for a buzzer according to the present invention is electrically connected to a buzzer and comprises a driving unit and a boost unit. The driving unit receives an analog audio signal and outputs a driving voltage to the buzzer based on the analog audio signal. The boost unit is electrically connected to the driving unit and boosts an input voltage to generate an operating voltage for the driving unit.

In line with the aspects of the present invention, a driving method for a buzzer is also provided, which comprises boosting an input voltage to generate an operating voltage; receiving an analog audio signal; and outputting a driving voltage based on the analog audio signal.

Compared to conventional techniques that drive a buzzer using a pulse-width modulation (PWM) signal, the driving system and method for a buzzer according to the present invention generate the required driving voltage for the buzzer through an analog signal. As a result, the buzzer is no longer limited to responding only to digital signals and emitting a single tone, but is instead capable of reproducing sound quality and details comparable to those of a conventional speaker, thereby ensuring high-quality audio output from the buzzer.

### BRIEF DESCRIPTION OF THE DRAWINGS

FIG. 1 is a block diagram illustrating a driving system for a buzzer according to an embodiment of the present invention.

FIG. 2 is a block diagram illustrating another driving system for a buzzer according to another embodiment of the present invention.

FIG. 3 is a block diagram illustrating a driving system for a buzzer according to yet another embodiment of the present invention.

FIG. 4 is a flowchart illustrating the driving method for a buzzer according to an embodiment of the present invention.

### DETAILED DESCRIPTION

The primary aspect of the present invention is to provide a driving system and a driving method for a buzzer 2, which enables the buzzer 2 to operate through an analog signal, thereby ensuring that the operation of the buzzer 2 is not restricted by whether the signal is in analog or digital form. Moreover, the present invention allows the buzzer 2 to benefit from the characteristics of analog signals, such that the sound emitted by the buzzer 2 is not limited to a single tone but comprises more detailed sound elements.

The following describes possible embodiments of the present invention in detail with reference to the drawings. However, it should be noted that the following embodiments are not intended to limit the scope of the claimed invention but are provided to facilitate understanding by those skilled in the art.

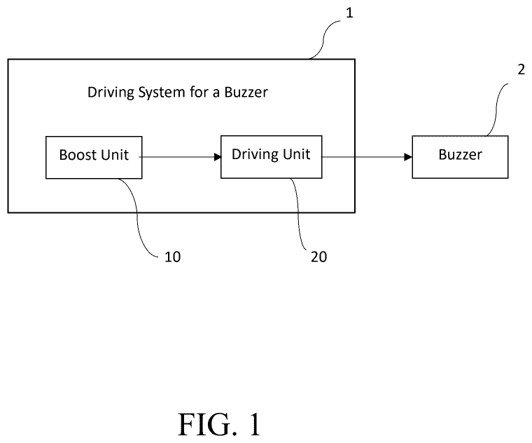

Referring to FIG. 1, the driving system 1 for a buzzer of the present invention is electrically connected to a buzzer 2 and comprises a boost unit 10 and a driving unit 20. The driving system 1 is independent of and separately disposed from the buzzer 2, making it directly applicable to an existing buzzer 2 without requiring modifications to the buzzer 2 architecture.

The boost unit 10 can be electrically connected to an external input power source and receives an input voltage provided by the input power source. The boost unit 10 boosts the input voltage to generate an operating voltage and outputs the operating voltage to the driving unit 20. That is, a boost ratio of the boost unit 10 is a ratio of the operating voltage to the input voltage. The voltage level of the operating voltage output by the boost unit 10 can be preset according to the operational requirements of the driving unit 20 and the buzzer 2, whereas the input voltage level may fluctuate based on the condition of the input power source.

For example, the operating voltage may be preset to 18V, while the input voltage may vary within a range of 2V to 5V. Regardless of the fluctuations in the input voltage, the boost unit 10 consistently boosts the input voltage to the preset 18V before outputting it to the driving unit 20, thereby ensuring the stability of the driving unit 20 operation without being affected by variations in the input voltage.

The driving unit 20 is electrically connected to the boost unit 10 and the buzzer 2. The driving unit 20 receives an analog audio signal corresponding to the buzzer 2 and outputs a driving voltage to the buzzer 2 based on the analog audio signal, causing the buzzer 2 to emit sound according to the driving voltage.

The driving unit 20 is powered by the operating voltage provided by the boost unit 10. The boost unit 10 raises the voltage level at the output stage of the driving unit 20 by providing the operating voltage, thereby increasing the voltage level of the driving voltage generated by the driving unit 20 and correspondingly enhancing the volume output of the buzzer 2 when driven by the driving voltage.

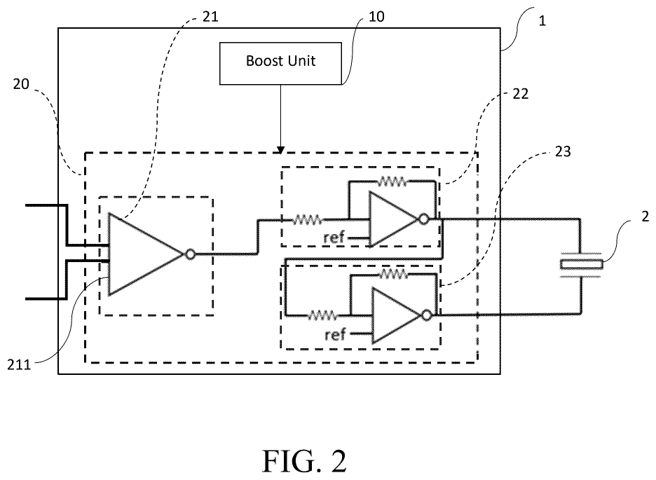

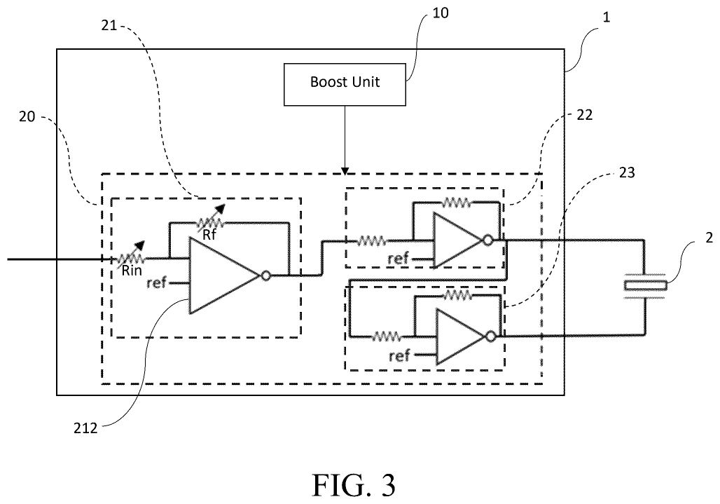

Referring to FIG. 2 and FIG. 3, the driving unit 20 comprises a gain control circuit 21, a first-stage amplifier circuit 22, and a second-stage amplifier circuit 23. The gain control circuit 21 amplifies the analog audio signal based on an amplification factor to generate a single-ended signal. The driving unit 20 then outputs the driving voltage to the buzzer 2 based on the single-ended signal. The amplification factor of the gain control circuit 21 can be set corresponding to the boost ratio of the boost unit 10, meaning the amplification factor is proportional to the boost ratio. That is, an amplification factor is set based on a boost ratio by which the input voltage is boosted to the operating voltage.

The first-stage amplifier circuit 22 has a first input terminal, a second input terminal, and an output terminal. The first input terminal of the first-stage amplifier circuit 22 is electrically connected to the gain control circuit 21 to receive the single-ended signal. The second input terminal of the first-stage amplifier circuit 22 is electrically connected to a reference voltage (Voltage Reference, ref). The output terminal of the first-stage amplifier circuit 22 is electrically connected to the positive electrode of the buzzer 2. After amplifying the single-ended signal, the first-stage amplifier circuit 22 outputs a first voltage through its output terminal.

The second-stage amplifier circuit 23 has a first input terminal, a second input terminal, and an output terminal. The first input terminal of the second-stage amplifier circuit 23 is electrically connected to the output terminal of the first-stage amplifier circuit 22 to receive the first voltage. The second input terminal of the second-stage amplifier circuit 23 is electrically connected to the reference voltage ref. The output terminal of the second-stage amplifier circuit 23 is electrically connected to the negative electrode of the buzzer 2. After amplifying the first voltage, the second-stage amplifier circuit 23 outputs a second voltage through its output terminal.

The driving voltage corresponds to the difference between the first voltage and the second voltage. The driving unit 20 outputs the driving voltage to the buzzer 2 through the first-stage amplifier circuit 22 and the second-stage amplifier circuit 23, thereby driving the buzzer 2 to emit sound corresponding to the driving voltage.

In one embodiment, the analog audio signal may comprise a human voice audio signal, a speech audio signal, or a music audio signal. In another embodiment, the analog audio signal may comprise an audio signal processed with specific frequency band adjustments, such as attenuation or enhancement of specific frequency bands. Additionally, the analog audio signal may be generated by applying low-pass filtering to a digital signal, such as a PWM signal.

In the embodiment shown in FIG. 2, the gain control circuit 21 of the driving unit 20 is a differential amplifier 211 with a pair of differential input terminals and an output terminal. The differential input terminals receive the analog audio signal, and the output terminal of the differential amplifier 211 is electrically connected to the first input terminal of the first-stage amplifier circuit 22. The differential amplifier 211 amplifies the analog audio signal according to the amplification factor to generate the single-ended signal, which is then output to the first-stage amplifier circuit 22. The analog audio signal may be a differential signal, where one of the differential input terminals receives the positive component of the analog audio signal, while the other receives the negative component.

The present invention not only allows the differential amplifier 211 to amplify the voltage of the analog audio signal but also enables it to suppress common-mode noise in the analog audio signal, thereby improving the quality of the single-ended signal.

In the embodiment shown in FIG. 3, the gain control circuit 21 of the driving unit 20 comprises an amplifier 212, an input resistor Rin, and a feedback resistor Rf. The negative input terminal of the amplifier 212 is connected in series with the input resistor Rin, while the negative input terminal and the output terminal of the amplifier 212 are connected in series with the feedback resistor Rf. The positive input terminal of the amplifier 212 receives the reference voltage ref, and the output terminal of the amplifier 212 is electrically connected to the first input terminal of the first-stage amplifier circuit 22. The amplification factor of the gain control circuit 21 corresponds to the resistance ratio of the feedback resistor Rf to the input resistor Rin. The driving unit 20 can adjust the amplification factor by modifying the resistance values of the feedback resistor Rf and the input resistor Rin, which may be variable resistors.

The buzzer 2 may be a piezoelectric buzzer, which primarily comprises a piezoelectric element, a metal diaphragm, and a housing. The piezoelectric element may be made of a piezoelectric ceramic material. When a voltage is applied, the piezoelectric element deforms due to the piezoelectric effect, thereby driving the metal diaphragm to vibrate and produce sound. The housing not only encloses the piezoelectric element and the metal diaphragm but also forms a resonance chamber for the piezoelectric element and the metal diaphragm.

Compared to conventional speakers, the buzzer 2 has advantages such as low power consumption, high sound output, small size, low cost, and high durability. Furthermore, due to its structural and material properties, the buzzer 2 exhibits excellent durability and stability even in extreme environments such as high temperatures or humidity. In contrast to speakers, which are prone to damage and have a higher unit cost, the buzzer 2 possesses irreplaceable advantages.

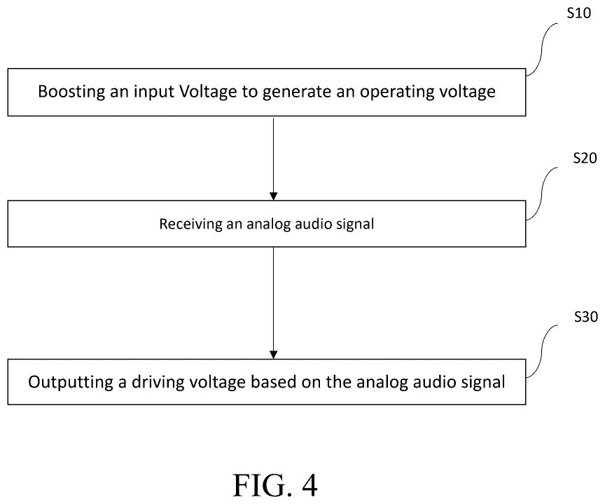

Referring to FIG. 4, the driving method for a buzzer according to the present invention is applied to the buzzer 2 and may be executed by the driving system 1 for the buzzer. The driving method for the buzzer comprises the following steps:

S10: Boosting an input voltage to generate an operating voltage. Step S10 may be executed by the boost unit 10, where the input voltage is boosted to the operating voltage based on a predetermined boost ratio.

S20: Receiving an analog audio signal. Step S20 may be executed by the driving unit 20, and the analog audio signal may be a differential signal.

S30: Outputting a driving voltage to the buzzer 2 based on the analog audio signal. Step S30 may be executed by the driving unit 20.

In a preferred embodiment, step S30 can include step of setting an amplification factor based on the boost ratio, amplifying the analog audio signal based on the amplification factor to generate a single-ended signal, and outputting the driving voltage based on the single-ended signal. The driving voltage corresponds to the difference between a first amplified voltage and a second amplified voltage, where the first amplified voltage is generated by amplifying the single-ended signal, and the second amplified voltage is generated by further amplifying the first amplified voltage.

In summary, the driving system 1 for a buzzer and the corresponding method according to the present invention are capable of processing analog audio signals to generate the driving voltage required by the buzzer 2. Compared to the conventional method of driving the buzzer 2 using a pulse-width modulation (PWM) signal, the present invention allows the buzzer 2 to operate beyond digital signal applications that limit it to emitting a single tone. Instead, by utilizing an analog signal, the present invention preserves the sound details of the original audio signal, enabling the buzzer 2 to achieve a sound quality comparable to that of conventional speakers while maintaining advantages such as high sound output, low component cost, and high durability.

The present invention is disclosed in the foregoing description based on preferred embodiments. However, it should be understood by those skilled in the art that these embodiments are provided solely for describing the invention and should not be construed as limiting the claimed scope of the patent rights. Any modifications or substitutions equivalent to the disclosed embodiments should be interpreted as being within the spirit and scope of the present invention. Accordingly, the protection scope of the present invention shall be defined by the claims set forth below.

What is claimed is:

1. A buzzer driving system electrically connected to a buzzer, and the buzzer driving system comprising:
a driving unit configured to receive an analog audio signal and output a driving voltage to the buzzer based on the analog audio signal; and
a boost unit electrically connected to the driving unit and configured to boost an input voltage to generate an operating voltage for the driving unit.

2. The buzzer driving system of claim 1,
wherein the driving unit comprises a gain control circuit, and the gain control circuit is configured to amplify the analog audio signal based on an amplification factor to generate a single-ended signal;
wherein the driving unit outputs the driving voltage to the buzzer based on the single-ended signal.

3. The buzzer driving system of claim 2,
wherein the analog audio signal is a differential signal; and
wherein the gain control circuit comprises a differential amplifier having a pair of differential input terminals configured to receive the analog audio signal, and an output terminal configured to output the single-ended signal.

4. The buzzer driving system of claim 2, wherein the driving unit is configured to set the amplification factor based on a boost ratio by which the input voltage is boosted to the operating voltage.

5. The buzzer driving system of claim 4,
wherein the gain control circuit comprises an amplifier, an input resistor, and a feedback resistor, wherein a negative input terminal of the amplifier is connected in series with the input resistor, and a negative input terminal and an output terminal of the amplifier are connected in series with the feedback resistor;
wherein the driving unit is configured to control the amplification factor by adjusting a resistance ratio between the input resistor and the feedback resistor based on the boost ratio.

6. The buzzer driving system of claim 2, wherein the driving unit comprises,
a first-stage amplifier circuit electrically connected to the gain control circuit, and configured to output a first amplified voltage at an output terminal based on a single-ended signal received at a negative input terminal and a reference voltage received at a positive input terminal; and
a second-stage amplifier circuit electrically connected to the output terminal of the first-stage amplifier circuit, and configured to output a second amplified voltage at an output terminal based on the first amplified voltage received at a negative input terminal and the reference voltage received at a positive input terminal;
wherein the driving voltage corresponds to a difference between the first amplified voltage and the second amplified voltage.

7. A method for driving a buzzer, and the method comprising:
boosting an input voltage to generate an operating voltage;
receiving an analog audio signal; and
outputting a driving voltage based on the analog audio signal.

8. The method of claim 7, wherein
an amplification factor is set based on a boost ratio by which the input voltage is boosted to the operating voltage,
the analog audio signal is amplified based on the amplification factor to generate a single-ended signal, and the driving voltage is output based on the single-ended signal.

9. The method of claim 8, wherein the single-ended signal is amplified to generate a first amplified voltage, the first amplified voltage is further amplified to generate a second amplified voltage, and the driving voltage corresponds to a difference between the first amplified voltage and the second amplified voltage.

10. The method of claim 7, wherein the analog audio signal is a differential signal.
